(19) United States
(12) Patent Application Publication
(10) Pub. No.: US 2022/0405628 A1
(43) Pub. Date: Dec. 22, 2022

(54) QUANTUM SYSTEMS AND METHODS FOR MAKING AND USING THEREOF

(71) Applicants: University of Florida Research Foundation, Inc., Gainesville, FL (US); UNIVERSIDAD DE LOS ANDES, BOGOTA (CO)

(72) Inventors: Juan C. NINO, Gainesville, FL (US); Juan G. RAMIREZ, Bogota (CO)

(21) Appl. No.: 17/821,701

(22) Filed: Aug. 23, 2022

Related U.S. Application Data
(63) Continuation-in-part of application No. PCT/US2021/019868, filed on Feb. 26, 2021.
(60) Provisional application No. 62/982,861, filed on Feb. 28, 2020.

(51) Int. Cl. G06N 10/40; B82Y 30/00

(52) U.S. Cl. CPC G06N 10/40; B82Y 30/00

(57) ABSTRACT

Described herein are chemically assembled nanoparticles of a multiferroic material embedded into a conductive (e.g., metal-organic) framework host that allows for tunable qubit spacing and overall architecture. In certain aspects, the composites described herein can function as solid-state qubits. In other aspects, the composites described herein can be implemented in systems used in quantum information processing (QIP). In other aspects, the composites described herein can be used as a quantum sensor.

### CROSS REFERENCE TO RELATED APPLICATIONS

This application is a continuation-in-part of international application no. PCT/US2021/019868 filed on Feb. 26, 2021, which claims priority upon U.S. provisional application Ser. No. 62/982,861 filed on Feb. 28, 2020. This application is hereby incorporated by reference in its entirety.

### BACKGROUND

The development of artificial quantum-coherent systems with unprecedented functionality is a research priority. To advance Quantum Information Science (QIS), there are several characteristics that a quantum system should possess including scalability, initialization, long coherence times (low noise), and be individually measurable. In addition, it would be extremely useful if the spin state is conserved at room temperature, its magnetic moment is tunable and more importantly, if the spin state can be accessed via electrical methods rather than magnetic detection methods.

### SUMMARY

Described herein are chemically assembled nanoparticles of a multiferroic material embedded into a conductive (e.g., metal-organic) framework host that allows for tunable qubit spacing and overall architecture.

The advantages of the invention will be set forth in part in the description which follows, and in part will be obvious from the description, or may be learned by practice of the aspects described below. The advantages described below will be realized and attained by means of the elements and combinations particularly pointed out in the appended claims. It is to be understood that both the foregoing general description and the following detailed description are exemplary and explanatory only and are not restrictive.

### BRIEF DESCRIPTION OF THE DRAWINGS

Many aspects of the present disclosure can be better understood with reference to the following drawings. The components in the drawings are not necessarily to scale, emphasis instead being placed upon clearly illustrating the principles of the present disclosure. Moreover, in the drawings, like reference numerals designate corresponding parts throughout the several views.

FIGS. 1A-1E show (a) X-ray diffractograms of BFO NPs calcined at different temperatures. Dominant secondary phases Bi₂O₄, β-Bi₂O₃ and Bi₂₅FeO₄₀ are indicated with Δ, * and + symbols respectively. Less intense secondary phases ε-Bi₂O₃ and Bi₂Fe₄O are not indicated but they were also identified and included in diffractograms Rietveld refinements. Rietveld refinements for 400° C. and 630° C. are shown in (b) y (c). Inset Diffractogram zoom around 2θ˜32° for samples calcined at 400° C. and 630° C. showing the reflections of (104) and (110) planes. (110) corresponding peak is shifted to lower angles as NP size decreases, as the arrow indicates. Typical R3c rhombohedral reflections planes for BFO are indicated in (b,d) BFO perovskite unit cell in pseudocubic representation. Octahedral organization of Fe and O ions is showed indicating Fe—O bonds. (e) Lattice parameters (calculated with refinements) ratio c/a, and microstrain (roughly estimated without the instrumental broadening) as functions of T_{cal} indicating increment of strain with NPs size decrease.

FIGS. 2A-2F show Raman spectra of NPs calcined at (a) 400° C., (b) 460° C., (c) 500° C., (d) 580° C. and (e) 630° C. Symbols represent observed spectra in each figure. Figures also show spectra fitting curves and deconvoluted individual peaks that have been labeled with corresponding indices according to symmetry of Raman modes expected for the BFO. (f) Red shift of A₁-4 peak with T w increase. (g) A₁-1 peak integral intensity increase with higher calcination temperature.

FIGS. 3A-3D show (a) TEM image of BFO NPs calcined at 400° C. Inset: Histogram of the NPs size distribution obtained from the TEM image. The lognormal fit is also shown. (c) TEM image of a single nanoparticle and (d) corresponding Fourier transform.

FIGS. 4A-4F show (a-d) ZFC-FC magnetization curves of the NPs for H=1 kOe. (e) Blocking temperature obtained from the derivative method and lognormal fittings for (a-d) ZFC-FC curves. (f) Mean blocking temperature T_{B} as a function of the calcination temperature of the NPs.

FIGS. 5A-5F show (a) magnetic hysteresis loops taken at room temperature and (b) at 5 K of BFO NPs prepared at different calcination temperatures (T_{cal}). The red line represents the fit using a Langevin equation. (c) Best fitting-parameters for N (number of NPs per mass unit) and (d) m (particle magnetic moment in Bohr magnetons units) with the calcination temperature for M vs. H experimental curves taken at 300 K and 5 K. (e) M vs H hysteresis at 2 K and 300 K curve for a NPs sample calcined at 600° C. (f) Hysteresis loop zoom; 2 K curve exhibits exchange bias effect.

FIGS. 6A-6F show (a) AFM topography image of BFO NPs calcined at 630° C. Spots on which hysteresis PFM curves were measured are shown. Curves (b-d) are the phase (blue) and amplitude (red) ferroelectric hysteresis loops corresponding to spots 1 to 3 on BFO nanoparticles, respectively. (e) AFM topography image of nearly 25 nm BFO NP calcined at 600° C. (f) On marked spot was measured phase and amplitude piezoelectric hysteresis loops.

FIG. 7 shows the magnetoelectric coefficient obtained in a pellet made of a BFO nanoparticle powder. The applied dc magnetic field was 80 mT and the AC magnetic field amplitude was 0.5 mT. The results demonstrate the mechanism by which the magnetic state of the nanoparticle can be controlled via voltage.

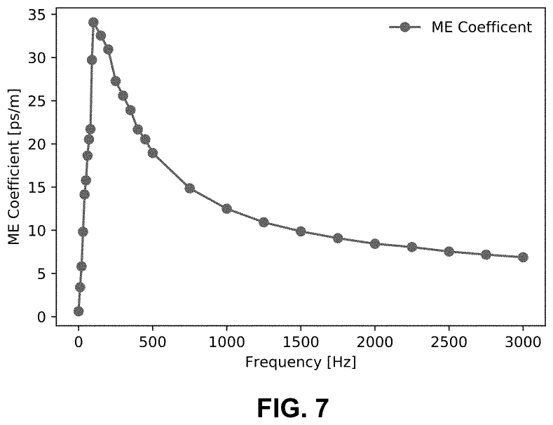

### DETAILED DESCRIPTION

Before the present materials, articles and/or methods are disclosed and described, it is to be understood that the aspects described below are not limited to specific compounds, synthetic methods, or uses, as such may, of course, vary. It is also to be understood that the terminology used herein is for the purpose of describing particular aspects only and is not intended to be limiting.

In the specification and in the claims that follow, reference will be made to a number of terms that shall be defined to have the following meanings:

As used herein, “comprising” is to be interpreted as specifying the presence of the stated features, integers, steps, or components as referred to, but does not preclude the presence or addition of one or more features, integers, steps, or components, or groups thereof. Moreover, each of the terms “by”, “comprising,” “comprises”, “comprised of,” “including,” “includes,” “included,” “involving,” “involves,” “involved,” and “such as” are used in their open, non-limiting sense and may be used interchangeably. Further, the term “comprising” is intended to include examples and aspects encompassed by the terms “consisting essentially of” and “consisting of.” Similarly, the term “consisting essentially of” is intended to include examples encompassed by the term “consisting of.

It must be noted that, as used in the specification and the appended claims, the singular forms “a,” “an,” and “the” include plural referents unless the context clearly dictates otherwise. Thus, for example, reference to “a multiferroic compound” includes mixtures of two or more multiferroic compounds and the like.

“Optional” or “optionally” means that the subsequently described event or circumstance can or cannot occur, and that the description includes instances where the event or circumstance occurs and instances where it does not.

It should be noted that ratios, concentrations, amounts, rates, and other numerical data can be expressed herein in a range format. It will be further understood that the endpoints of each of the ranges are significant both in relation to the other endpoint, and independently of the other endpoint. It is also understood that there are a number of values disclosed herein, and that each value is also herein disclosed as “about” that particular value in addition to the value itself. For example, if the value “10” is disclosed, then “about 10” is also disclosed. Ranges can be expressed herein as from “about” one particular value, and/or to “about” another particular value. Similarly, when values are expressed as approximations, by use of the antecedent “about,” it will be understood that the particular value forms a further aspect. For example, if the value “about 10” is disclosed, then “10” is also disclosed and “about 5 to about 15” is also disclosed.

When a range is expressed, a further aspect includes from the one particular value and/or to the other particular value. For example, where the stated range includes one or both of the limits, ranges excluding either or both of those included limits are also included in the disclosure, e.g. the phrase “x to y” includes the range from ‘x’ to ‘y’ as well as the range greater than ‘x’ and less than ‘y’. The range can also be expressed as an upper limit, e.g. ‘about x, y, z, or less’ and should be interpreted to include the specific ranges of ‘about x’, ‘about y’, and ‘about z’ as well as the ranges of ‘less than x’, less than y’, and ‘less than z’. Likewise, the phrase ‘about x, y, z, or greater’ should be interpreted to include the specific ranges of ‘about x’, ‘about y’, and ‘about z’ as well as the ranges of ‘greater than x’, greater than y’, and ‘greater than z’. In addition, the phrase “about ‘x’ to ‘y’”, where ‘x’ and ‘y’ are numerical values, includes “about ‘x’ to about ‘y’”.

It is to be understood that such a range format is used for convenience and brevity, and thus, should be interpreted in a flexible manner to include not only the numerical values explicitly recited as the limits of the range, but also to include all the individual numerical values or sub-ranges encompassed within that range as if each numerical value and sub-range is explicitly recited. To illustrate, a numerical range of “about 0.1% to 5%” should be interpreted to include not only the explicitly recited values of about 0.1% to about 5%, but also include individual values (e.g., about 1%, about 2%, about 3%, and about 4%) and the sub-ranges (e.g., about 0.5% to about 1.1%; about 5% to about 2.4%; about 0.5% to about 3.2%, and about 0.5% to about 4.4%, and other possible sub-ranges) within the indicated range.

As used herein, the term “about” is used to provide flexibility to a numerical range endpoint by providing that a given numerical value may be “a little above” or “a little below” the endpoint without affecting the desired result. For purposes of the present disclosure, “about” refers to a range extending from 10% below the numerical value to 10% above the numerical value.

As used herein, the term “admixing” is defined as mixing two or more components together so that there is no chemical reaction or physical interaction. The term “admixing” also includes the chemical reaction or physical interaction between the two or more components.

As used herein, a plurality of items, structural elements, compositional elements, and/or materials may be presented in a common list for convenience. However, these lists should be construed as though each member of the list is individually identified as a separate and unique member. Thus, no individual member of any such list should be construed as a de facto equivalent of any other member of the same list based solely on its presentation in a common group, without indications to the contrary.

Concentrations, amounts, and other numerical data may be expressed or presented herein in a range format. It is to be understood that such a range format is used merely for convenience and brevity and thus should be interpreted flexibly to include not only the numerical values explicitly recited as the limits of the range, but also to include all the individual numerical values or sub-ranges encompassed within that range as if each numerical value and sub-range was explicitly recited. As an example, a numerical range of “about 1” to “about 5” should be interpreted to include not only the explicitly recited values of about 1 to about 5, but also to include individual values and sub-ranges within the indicated range. Thus, included in this numerical range are individual values such as 2, 3, and 4, the sub-ranges such as from 1-3, from 2-4, from 3-5, from about 1-about 3, from 1 to about 3, from about 1 to 3, etc., as well as 1, 2, 3, 4, and 5, individually. The same principle applies to ranges reciting only one numerical value as a minimum or maximum. The ranges should be interpreted as including endpoints (e.g., when a range of “from about 1 to 3” is recited, the range includes both of the endpoints 1 and 3 as well as the values in between). Furthermore, such an interpretation should apply regardless of the breadth or range of the characters being described.

Disclosed are materials and components that can be used for, can be used in conjunction with, can be used in preparation for, or are products of the disclosed compositions and methods. These and other materials are disclosed herein, and it is understood that when combinations, subsets, interactions, groups, etc. of these materials are disclosed, that while specific reference to each various individual combination and permutation of these compounds may not be explicitly disclosed, each is specifically contemplated and described herein. For example, if a multiferroic compound is disclosed and discussed, and a number of different metal-organic frameworks are discussed, each and every combination of multiferroic compound and metal-organic framework that is possible is specifically contemplated unless specifically indicated to the contrary. For example, if a class of multiferroic compounds A, B, and C are disclosed, as well as a class of metal-organic frameworks D, E, and F, and an example combination of A+D is disclosed, then even if each is not individually recited, each is individually and collectively contemplated. Thus, in this example, each of the combinations A+E, A+F, B+D, B+E, B+F, C+D, C+E, and C+F is specifically contemplated and should be considered from disclosure of A, B, and C; D, E, and F; and the example combination A+D. Likewise, any subset or combination of these is also specifically contemplated and disclosed. Thus, for example, the sub-group of A+E, B+F, and C+E is specifically contemplated and should be considered from disclosure of A, B, and C; D, E, and F; and the example combination of A+D. This concept applies to all aspects of the disclosure including, but not limited to, steps in methods of making and using the disclosed compositions. Thus, if there are a variety of additional steps that can be performed with any specific embodiment or combination of embodiments of the disclosed methods, each such composition is specifically contemplated and should be considered disclosed.

Described herein are composites comprising a metal-organic framework and a plurality of nanoparticles comprising a multiferroic compound incorporated within the metal-organic framework. Provided below are the components used to make the composites as well as methods for making and using the same.

### Nanoparticles of Multiferroic Compounds

The composites described herein include a plurality of nanoparticles comprising a multiferroic compound. The term “multiferroic compound” as used herein is defined as a material that has at least two ferroic orders. In one aspect, the multiferroic compound is a material that has the properties of ferromagnetism and ferroelectricity coexisting at a given temperature.

The nanoparticles comprising the multiferroic compound can be prepared using a number of techniques. In one aspect, the nanoparticles are prepared by a sol-gel method. The Examples provide non-limiting procedures for producing the nanoparticles described herein.

The size of the nanoparticles can be modified to modify the properties of the composite. In one aspect, the nanoparticles can be calcined at different temperature to modify nanoparticle size. In one aspect, the nanoparticles are calcined at a temperature of from about 400° C. to about 650° C., or about 400° C., about 450° C., about 500° C., about 550° C., about 600° C., or about 650° C., where any value can be a lower and upper endpoint of a range (e.g., about 450° C. to about 600° C., etc.). In one aspect, the nanoparticles have a mean diameter of from about 1 nm to about 100 nm, or about 1 nm, about 5 nm, about 10 nm, about 20 nm, about 30 nm, about 40 nm, about 50 nm, about 60 nm, about 70 nm, about 80 nm, about 90 nm, or about 100 nm, where any value can be a lower and upper endpoint of a range (e.g., about 20 nm to about 80 nm, etc.). The Examples provide non-limiting procedures for modifying the diameter of the nanoparticles described herein.

In one aspect, the multiferroic compound is BiFeO₃ (BFO). BFO is an archetypical room-temperature multiferroic material with rhombohedral distorted perovskite structure that belongs to the R3c space group. BFO displays a Dzyaloshinskii-Moriya (DM) interaction among nearest neighbor Fe₃₊ spins that produces an antiferromagnetic long-cycloid spin structure of wavelength 62 nm. BFO has a high Néel temperature (640K) and high Curie transition temperature (1100K), as well as high polarization of Ps=˜100 μC/cm₂ in the [111] crystallographic direction. In one aspect, low-dimensional confinement of BFO produces (i) a strengthening of the magnetoelectrical (ME) coupling and (ii) a ferromagnetic-like behavior when particle size is smaller than its long-cycloid spin structure. Not wishing to be bound by theory, this unique combination of properties emerges due to the multiple degrees of freedom (lattice, spin, and orbital) present in multiferroic BFO that can be used to produce tunable spin systems using charge currents at room temperature.

In one aspect, when the multiferroic compound is BiFeO₃, the multiferroic compound is produced by (a) admixing a Bi⁺³ compound with a Fe⁺³ compound in water to produce a first composition, (b) adding a glycol to the first composition to produce a second composition, and (c) heating the second composition at temperature of from about 400° C. to about 650° C. to produce the multiferroic compound. In one aspect, the Bi⁺³ compound and the Fe⁺³ compound are each a salt. In another aspect, the Bi⁺³ compound is BiX₃ and the Fe⁺³ compound is FeX₃, where X is a nitrate group or a halide (e.g., F, Cl, Br).

In one aspect, the Bi⁺³ compound and the Fe⁺³ compound are admixed in water with or without a cosolvent. The relative amount of the Bi⁺³ compound and the Fe⁺³ compound can vary. In one aspect, equimolar amounts of the Bi⁺³ compound and the Fe⁺³ compound are used to produce the multiferroic compound. In one aspect, the Bi⁺³ compound and the Fe⁺³ compound are admixed in water from about 20° C. to about 30° C. In one aspect, an organic acid can be added to the first composition and heating the first composition at a temperature of from about 50° C. to about 100° C., or about 50° C., about 60° C., about 70° C., about 80° C., about 90° C., or about 100° C., where any value can be a lower and upper endpoint of a range (e.g., about 60° C. to about 80° C., etc.).

After the Bi⁺³ compound and the Fe⁺³ compound are admixed, a glycol is added to produce a precursor gel. The glycol can be any organic compound with two or more hydroxyl groups. In one aspect, the glycol can be ethylene glycol, propylene glycol, or a combination thereof. In one aspect, the glycol is added to the first composition at a temperature of from about 80° C. to about 100° C., or about 80° C., about 85° C., about 90° C., about 95° C., or about 100° C., where any value can be a lower and upper endpoint of a range (e.g., about 85° C. to about 95° C., etc.). After the glycol has been added, the composition is heated at temperature of from about 400° C. to about 650° C. to produce the multiferroic compound, or about 400° C., about 450° C., about 500° C., about 550° C., about 600° C., or about 650° C., where any value can be a lower and upper endpoint of a range (e.g., about 450° C. to about 600° C., etc.).

In other aspects, non-multiferroic compounds can be used. In one aspect, TbMnO₃ (28K) [Nature 426, 55-58(2003)] can be used herein.

### Metal-Organic Frameworks

The metal-organic frameworks (referred to herein as MOFs) are three dimensional structures composed of a plurality of pores and channels. The metal-organic frameworks are composed of a plurality of structural units arranged in a specific pattern.

The selection of the transition metal used to produce the metal-organic framework can vary depending upon the end-use of the composite. In one aspect, the metal ions used in the MOFs can be selected from metals capable of forming one or more coordination bonds with a mono-, di-, tri-, or tetra-valent ligand. In some embodiments, the one or more metals can be selected from a Group 2 metal or a metal belonging to any one of Groups 7-13 metal (wherein “Group” refers to a group of the Periodic Table), or a combination thereof. In some aspects, multiple metal ions of a single species, or a cluster thereof, can be used. In other aspects, multiple metal ions of two or more species, or a cluster thereof, can be used. In one aspect, the metal can be selected from copper, silver, gold, aluminum, zinc, cobalt, nickel, magnesium, manganese, iron, cadmium, beryllium, calcium, titanium, tin, chromium, vanadium, or any combination thereof.

In one aspect, the metal-organic framework materials described herein include one or more metal ions and one or more bridging organic ligands coupled to the metal ions. The metal ions and ligands can be coupled via coordination bonds that can be covalent and/or ionic (e.g., electrostatic). The MOFs disclosed herein can be made to exhibit high surface area and tunable nanostructured cavities and can be modified both chemically and physically.

The organic ligands used in the MOFs disclosed herein can be selected from mono-, di-, tri-, or tetra-valent ligands. In some aspects, the ligand can be a bidentate carboxylic acid ligand (or a carboxylate thereof), a tri-dentate carboxylic acid ligand (or carboxylate thereof), an azole ligand, or a combination thereof. Exemplary ligands include, but are not limited to, oxalic acid, malonic acid, succinic acid, glutaric acid, phthalic acid, terephthalic acid, citric acid, trimesic acid, benzene-1,3,5-tricarboxylic acid (BTC), 4,6-dioxido-1,3-benzenedicarboxylate (DOBDC), 1,2,3-triazole, pyrrodizaole, squaric acid, 1,4-diazabicyclo[2.2.2]octane) (DABCO), 1,4-naphthalenedicarboxylate (NDC), 3,6-di(pyridin-4-yl)-1,2,4,5-tetrazine (DPTZ), N,N′-di(4-pyridyl)-1,4,5,8-naphthalenediimide (dpNDI), biphenyldicarboxylate, and combinations thereof.

In other aspects, the MOF material can be modified to improve the electronic conductivity of the MOF material. In one aspect, the electronic conductivity can be improved or enhanced by including a dopant, such as I₂, into the MOF material. In other aspects, the MOF comprises a Ti₁₂O₁₅ oxocluster and a tetracarboxylate ligand (S. Wang et al. Nat. Comm. 9, 1660 (2018)). In other aspects, the MOF can be modified to include redox-active molecule, such as an organocyanide moiety, an organocyanide-containing ligand, and/or a polyaniline, to enhance the conductivity of the MOF material. Exemplary organocyanide-containing ligands include, but are not limited to, TCNQ, TCNE, DCNQI, or any combination thereof.

In one aspect, the MOF can be made by using a growth technique whereby layers of MOF material are deposited onto a substrate component, such as in a layer-by-layer (“LBL”) method. The layer-by-layer deposition technique can comprise immersing the substrate into an MOF precursor solution, a ligand solution, or a combination thereof. In some embodiments, the substrate is first immersed in the MOF precursor solution and then subsequently immersed in the ligand solution. In yet other embodiments, the order of immersion can be reversed, or the substrate can be immersed in a solution comprising a mixture of the MOF precursor and the ligand.

The MOF precursor solution can comprise any of the metals described above for use in the MOF. In one aspect, the MOF precursor solution can be selected from solutions comprising metal acetates, metal nitrates, or combinations thereof. Exemplary MOF precursors can include, but are not limited to, Cu(OAc)₂, Zn(OAc)₂, Ni(OAc)₂, Zn(NO₃)₂.6H₂O, Cu(NO₃).₂2.5H₂O, and Co(NO₃)₂.6H₂O. In one aspect, the metal precursor and/or the ligand can be combined with a solvent, such as an alcohol (e.g., methanol, ethanol, isopropanol, etc.), water, or a mixture thereof. The substrate can be rinsed with solvent and dried under an inert gas between each application of the metal precursor, ligand, or combination thereof.

In one aspect, the MOF can be provided as or grown as a thin film or a thick film. Exemplary thin films can have a thickness ranging from greater than zero nanometers to several hundred nanometers, such as 1 nm to 500 nm or more. Exemplary thick films can have thicknesses ranging from at least 500 nm to several micrometers, such as 500 nm to 50 μm or more.

### Methods for Preparing the Composites

The composites can be prepare using a number of techniques. In one aspect, MOFs can be used as a template to hold guest nanoparticles. In this aspect, chemical vapor deposition, solid grinding, liquid impregnation, and double solvent methods, can be used to produce the composites. In another aspect, the process involves employing the encapsulation of pre-synthesized nanoparticles using self-sacrificing template techniques. The methods provided in Yu et al. Mater Horiz 4 [4] 557-569 (2017) 10.1039/c6mh00586a can be used herein to produce the composites.

By varying the MOF's geometrical characteristics, the distance between the nanoparticles can be tuned to enhance spin coherent times. Additionally, by varying the electrical conductivity of the MOF's, the control and accessibility of the individual spin states via electrical signals can be optimized.

### Applications of Composites

The composites described herein can function as solid-state qubits. The MOFs are built from molecular building blocks. The MOFs have synthetic tunability of interqubit interactions present in the composites with the benefits of solid-state systems. The molecular nature of MOFs also enables tuning of their phonon spectrum, which determines the interaction of qubits with the thermal energy of the environment. By selecting and modifying the chemical structure of the MOF, the coherence time of the qubit can be optimized. Coherence time describes the lifetime of the superposition state before it collapses into one of its constituent classical states.

The composites described herein can be implemented in systems used in quantum information processing (QIP). The use of the composites as qubits and incorporation into quantum computers has far-reaching applications. QIP could enable the solution of problems that would take the world's most powerful classical computers forever to solve. Thus, the composites described herein are a viable option in the field of QIP.

Quantum mechanical systems have been investigated for numerous applications including quantum computation, quantum communication and quantum cryptography. The computation and information processing based on quantum mechanical principles can outperform classical computation and information processing in a number of tasks like computational chemistry, cryptography, financial modelling, optimization, weather forecasting and in general solve Np-hard problems like prime factorization problems.

In other aspects, the composites described herein can be used as a quantum sensor. Not wishing to be bound by theory, the quantum states of qubits as sensors can be modified by manipulating the environment's effects on the qubit, thereby treating decoherence and similar phenomena as a detectable feature. Moreover, interactions of the qubits with adsorbed species in a MOF can give rise to chemical information about the qubit's surroundings. For example, the sensors with composites described herein can be used to perform thermometry and thermal mapping, sense nuclei and paramagnetic electrons in proximal proteins, and monitor single-neutron action potentials. In other aspects, the composites described herein can be used as sensors to detect analytes. The pore structure of the MOFs used herein can be modified for analyte selectivity.

Aspect 1: A composite comprising a conductive metal-organic framework and a plurality of nanoparticles comprising a multiferroic compound incorporated within the metal-organic framework.

Aspect 2: The composite of Aspect 1, wherein the multiferroic compound comprises BiFeO₃ (BFO).

Aspect 3: The composite of Aspect 2, wherein the multiferroic compound comprises BiFeO₃ nanoparticles calcined at temperature of from about 400° C. to about 650° C.

Aspect 4: The composite of Aspect 2 or 3, wherein the multiferroic compound is produced by (a) admixing a Bi⁺³ compound with a Fe⁺³ compound in water to produce a first composition, (b) adding a glycol to the first composition to produce a second composition, and (c) heating the second composition at temperature of from about 400° C. to about 650° C. to produce the multiferroic compound.

Aspect 5: The composite of Aspect 4, wherein the Bi⁺³ compound is BiX₃ and the Fe⁺³ compound is FeX₃, where X is a nitrate group or a halide.

Aspect 6: The composite of Aspect 4 or 5, wherein the Bi⁺³ compound and the Fe⁺³ compound are in equimolar amounts.

Aspect 7: The composite of any one of Aspects 4 to 6, wherein the Bi⁺³ compound and the Fe⁺³ compound are admixed in water from about 20° C. to about 30° C.

Aspect 8: The composite of any one of Aspects 4 to 7, further comprising adding an organic acid to the first composition and heating the first composition at a temperature of from about 50° C. to about 100° C.

Aspect 9: The composite of any one of Aspects 4 to 8, wherein the glycol comprises ethylene glycol, propylene glycol, or a combination thereof.

Aspect 10: The composite of any one of Aspects 4 to 9, wherein step (b) is performed at a temperature of from about 80° C. to about 100° C.

Aspect 11: The composite of any one of Aspects 2 to 10, wherein BFO has a rhombohedral perovskite structure with an R3c space group symmetry.

Aspect 12: The composite of any one of Aspects 1 to 11, wherein the nanoparticles have a mean diameter of from 1 nm to 100 nm.

Aspect 13: The composite of any one of Aspects 1 to 12, wherein the nanoparticles are incorporated into the metallic organic framework chemical vapor deposition, solid grinding, liquid impregnation, and double solvent methods.

Aspect 14: A system comprising the composite in any one of Aspects 1-13 used in quantum information processing (QIP).

Aspect 15: A sensor comprising the composite in any one of Aspects 1-13.

### Examples

The following examples are put forth so as to provide those of ordinary skill in the art with a complete disclosure and description of how the compounds, compositions, and methods described and claimed herein are made and evaluated and are intended to be purely exemplary and are not intended to limit the scope of what the inventors regard as their invention. Efforts have been made to ensure accuracy with respect to numbers (e.g., amounts, temperature, etc.) but some errors and deviations should be accounted for. Unless indicated otherwise, parts are parts by weight, temperature is in ° C. or is at ambient temperature, and pressure is at or near atmospheric. Numerous variations and combinations of reaction conditions (e.g., component concentrations, desired solvents, solvent mixtures, temperatures, pressures, and other reaction ranges and conditions) can be used to optimize the product purity and yield obtained from the described process. Only reasonable and routine experimentation will be required to optimize such process conditions.

### Preparation and Characterization of BFO

BFO NPs were prepared by sol-gel method; using an appropriate amount (to obtain a molar concentration of 0.0025 M in 25 mL of solution) of bismuth nitrate pentahydrate (Bi(NO₃)₃.5H₂O) which was dissolved in 8 mL of deionized water and 2 mL of glacial acetic acid (CH₃COOh); it was stirred at room temperature for 24 h. Then, deionized water was added until achieving a total of 25 mL of solution and the required amount of iron nitrate nonahydrate (Fe (NO₃)₃.9H₂O) to obtain 0.0025 M of the molar concentration of this reagent. This solution was stirred for 3 h and afterwards 0.5 mmol of citric acid (C₆H₈O₇) was added while the temperature was increased to a range between 70° C. and 75° C. Then, the pH of the solution was controlled by immediately adding drops of ammonium hydroxide until the solution turned into a translucid red.

Afterwards, the solution was continuously stirred while keeping the temperature fixed for another 8 hours. After that, 1.25 mmol of ethylene glycol (C₂H₆O₂) were added at 90° C., which produce the precursor gel. This gel was calcined for 3 h in an oven at different calcination temperatures, from 400° C. to 630° C. Finally, the resulting powder was washed out several times with deionized water and glacial acetic acid and dried at room temperature.

The crystal structure of the powder was determined by X-Ray diffraction (XRD). We used Cu-k_{α} radiation and angular range of 20 from 5 to 120 with step size 0.002 degrees to perform a meaningful Rietveld refinement using the Profex software. Raman spectroscopy was measured in the range of 50 cm⁻¹ to 1000 cm⁻¹ to characterize typical resonant modes found in BFO. The local structure and particle size were characterized by transmission electron microscopy (TEM) using a JEOL TEM-FEG (JEM 2100F, 300 KV) and JEOL TEM-MSC (JEM 2100, 200 KV). The images were acquired using a Gatan/Orius SC600/831 camera at different magnifications and analyzed using Gatan Micrograph software. The samples were prepared before the experiment by drying a drop of a dispersion on ultrathin carbon film supported on holey carbon (Ted Pella). The particle size also was characterized by field emission scanning electron microscopy (FE-SEM) Tescan LYRA 3. To image the particles, we dissolve them into isopropyl alcohol on an Al foil. The magnetization hysteresis curves (M vs H) at room temperature were obtained with a Lakeshorem vibrating sample magnetometer (VSM) and a Quantum Design™ SQUID magnetometer. Topography of individual NP was obtained with an Asylum Research MFP-3D™ AFM. The ferroelectric characteristics were measured in piezoelectric force microscopy (PFM) mode and switching spectroscopy (SS-PFM) mode¹⁴. The ferroelectric hysteresis loops on single BFO NP were made with a probe of Asylum AC240TM-R3 with Ptlr tip coating. BFO NPs were dissolved into isopropyl alcohol and dispersed using the spin coating onto an Au/Ti/SiO₂/Si and Ag/Ti/SiO₂/Si substrates to measure simultaneously the topography and ferroelectric characteristics of individual particles.

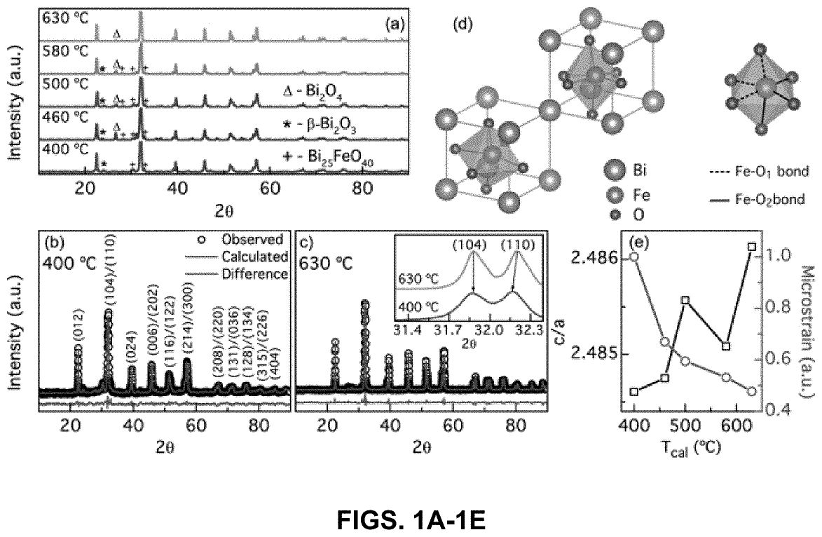

FIG. 1(a) shows the XRD pattern for BFO NPs calcined at five different temperatures (T_{cal}) from 400° C. to 630° C. In all samples, the peaks coincide with planes expected for BFO. Additional peaks can be attributed to secondary phases formed in the fabrication process. Rietveld refinements of the XRD patterns for nano-powders calcined from 400° C. to 630° C. are shown in FIG. 1(b,c). In FIG. 1(b) each peak is labeled with its corresponding Miller indices in hexagonal representation. The typical double peaks (104)/(110) around 2θ=32° from the BFO NPs calcined at 400° C. and 630° C. are shown in the inset of FIG. 1(c). The (110) peak shifts toward lower angles in the sample calcined at a temperature of 400° C., attributed to an increment of the crystal strain caused by NPs size confinement¹⁶. The BFO phase percentage obtained from the refinement was 70.7% and 90.5% for 400° C. and 630° C., respectively. The refinements confirm that our NPs have a rhombohedral perovskite structure with an R3c space group symmetry (Chi-square fittings are: χ2630=2.4 and χ2400=2.9). FIG. 1(d) shows a schematic construction of a BFO unit cell in a pseudocubic system. The perovskite structure, characterized by the octahedral coordination, can be observed. In the NPs calcined at 400° C., the lattices parameters calculated were a=b=5.5850 Å, and c=13.8764 Å; while for the NPs calcined at 630° C. were a=b=5.5810 Å, and c=13.8751 Å, which are in close agreement with bulk BFO reports¹⁵. FIG. 1(e) shows the evolution of the ratio c/a, and microstrain vs. T_{cal}. The microstrain was roughly estimated using the Williamson-Hall equation without including the correction due to instrumental broadening and normalized to the highest value, with the purpose of seeing the strain evolution trend across the samples. This anticorrelation between c/a ratio and microstrain shows that our NPs exhibits variations in the degree of crystal strain that decreases with T_{cal}.

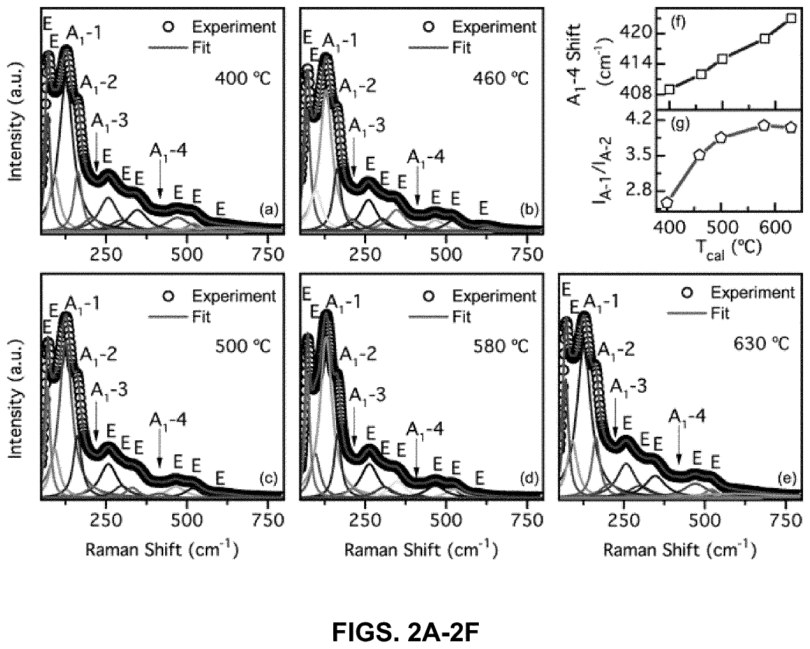

FIG. 2 shows the Raman spectra obtained at room temperature for the studied samples. We have identified 12 active modes (4 A₁ and 8 E) out of 13 modes present in bulk (4A₁+9E) in the Raman spectra by a peak-fitting procedure using Lorentzian distributions. Raman spectra of our NPs, for each T_{cal}, are in good agreement with those expected for rhombohedral BFO with a R3c space group. Therefore, we confirm that our NPs have the ferroelectric R3c phase. Because there are not considerable changes between the Raman spectra, we could infer that ferroelectric phase is present in all samples. However, an unexpected red shift of all A₁ peaks from the typical values reported for bulk BFO can be observed. Furthermore, such red shift increases with decreasing Tc and with respect to BFO bulk single crystal reported Raman shifts. For example, in the sample calcined at 400° C., we observe a red shift of 15.6% for the A₁-1 Raman mode, 8.5% for A₁-2 while for A₁-3 and A₁-4 we observe red shifts of 7.9% and 16.5%, respectively. In FIG. 2(f) we show the A₁-4 mode red shift evolution as a function of Tc; such mode is associated to Fe—O1 and Fe—O2 bonds (see FIG. 1(f)). From these results we can identify a possible distortion of Fe—O bonding distances or Fe—O—Fe bonding angle and relate them with the calcination. Indeed, such red shifts observed in Raman spectra and the analysis of the Williamson-Hall equation from XRD results could be related to the strain of NPs and the size confinement. Similarly, A₁-1 Raman peak suppression can be associated to an increase of the magnetoelectric coupling in BFO¹⁰. In our samples, such suppression increases with decreasing T_{cal}, as shown in FIG. 2(g) where the A₁-1 integral intensity I_{A1} (normalized to the A₁-2 integral intensity I_{A2}) increase with T_{cal}.

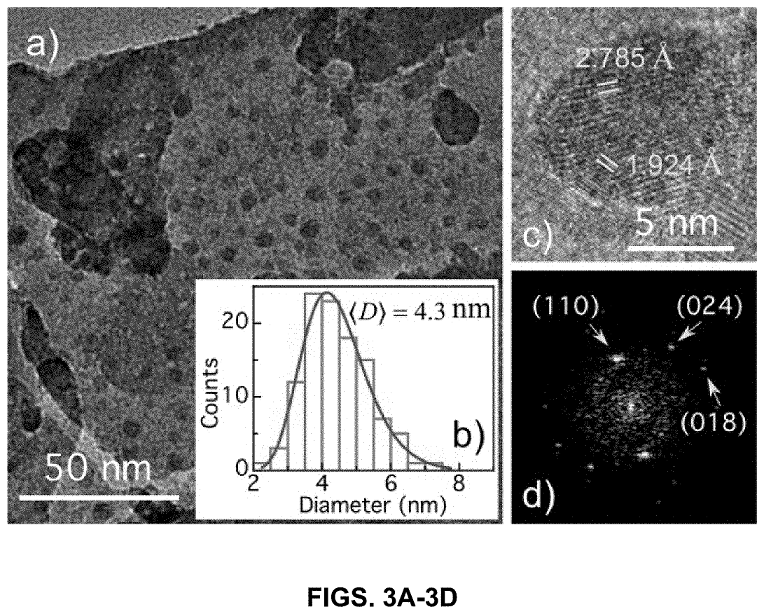

FIG. 3(a) shows a TEM image of NPs calcined at 400° C. Using this image, as well as others from several TEM images, the size distribution presented in FIG. 3(b) was built. The diameter distribution was fitted with a lognormal-type function, from which a mean diameter close to 4.3 nm was determined, as shown in the figure. High resolution TEM image of NP with nearly 10 nm diameter is shown in FIG. 3(c). Interplanar Bragg distances 2.785 Å and 1.924 Å can be identified in the NP, which are in good agreement with the distance between (110) and (024) lattice planes of BFO. From FFT of TEM image (see FIG. 3(d)), a third spot appears, whose interplanar distance of 1.632 Å coincide with that of (018) BFO lattices planes, additionally to (110) and (024) planes observed on high resolution image. From the lognormal-type function fitting we obtain a mean particle diameter close to 54 nm.

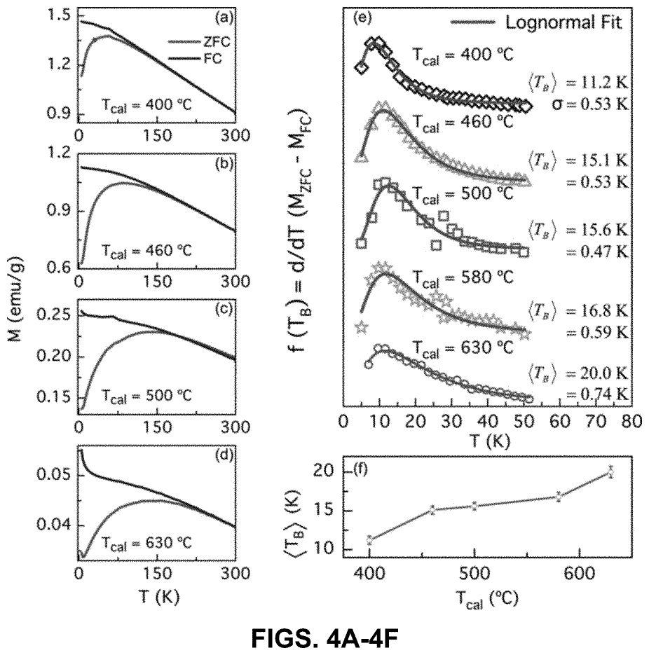

FIG. 4 shows the zero-field cooling and field cooling (ZFC-FC) magnetization curves for H=1 kOe applied field. For all samples, the FC magnetization decreases monotonically, while the ZFC curves reach a maximum (Tₘₐₓ), which appears at higher temperatures with increasing T_{cal}. The ZFC curves resemble the ones of magnetic nanoparticles with a superparamagnetic behavior. Thus, the temperature at which the maximum of the ZFC magnetization occurs can be ascribed to a blocking temperature (T_{B}), i.e., this temperature is closer to the one in which the system undergoes a blocking-to-unblocking transition. Upon increasing temperature, the ZFC and FC curves merge few degrees above the maximum reached by the ZFC curve. This point, known as the irreversibility temperature (Tᵢ), can be interpreted as an indicative of the existence of a blocking temperature distribution f(T_{B}), associated to a NP size distribution. We estimated f(T_{B}) in each sample using the reduced-magnetization derivative, calculated as ddT(MZFC−MFC). FIG. 4(i) shows f(T_{B}) distributions for all samples and it can be noticed that they can be well fitted with a lognormal-type function. The [symbol] TB [symbol] obtained range from 11.2 K for the sample calcined at 400° C. to 20.0 K in sample calcined at 630° C. The dependence of [symbol] TB [symbol] with Tc is plotted in FIG. 4(j). An increase of the Neel relaxation time could explain the increment of [symbol] TB [symbol] with Tw in our NPs. Thus, the blocked-superparamagnetic transition temperature increases with NP size, and therefore suggests that the NPs have a nearly superparamagnetic behavior.

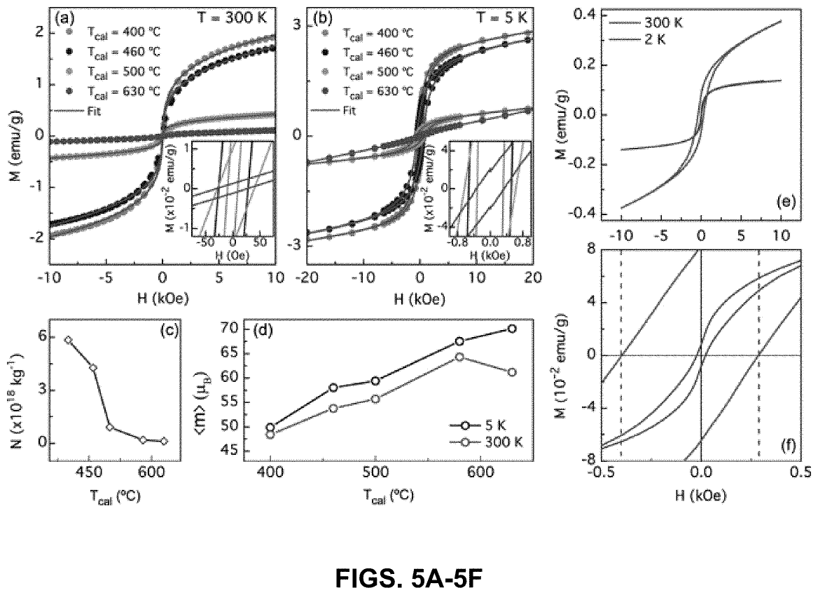

FIG. 5(a) shows the isothermal magnetization hysteresis loops (M vs. H) measured at 300 K for the studied BFO NPs. We found a S-shape and almost null values of the coercive field (H_{C}) resembling a near superparamagnetic-like behavior, which confirm that observed at ZFC-FC curves. At higher fields, up to 3 Tesla (not shown), the magnetization does not to reach saturation indicating the existence of a paramagnetic-like component, which is possibly related to those disordered magnetic moments located at the NP surface. The NPs magnetization increases with decreasing T_{cal}. In contrast, coercive field (H_{C}) drastically increase at low temperatures, as shown in FIG. 5(b) for T=5 K and can be attributed to a higher contribution from a ferromagnetic order. It can be noticed also that the paramagnetic component is present in all samples.

Fittings of the M vs. H curves were performed using a modified Langevin function (to include a H_{C} dependence) where we consider a lognormal-type distribution magnetic moments as suggested by our TEM and FE-SEM images and magnetic data. Finally, a linear parameter with the field in the fitting calculations was used to consider the paramagnetic contributions. Best fitting results are shown as continuous solid red lines in FIG. 5(a,b). Whit this procedure, the average magnetic moment per NP, [symbol] m [symbol] , and number of NPs per unit mass, N was obtained.

From FIG. 5(c) one can infer that N decreases monotonically with T_{cal}. On other hand, FIG. 5(d) shows the evolution of [symbol] m [symbol] as function of Tcal, at 300 K and 5 K. In both cases, an increase of [symbol] m [symbol] with T_{cal} is observed. This means that [symbol] m [symbol] increase with NP size as opposite to the total magnetization. Such behavior can be understood assuming that at a given NP size, exceeding the long-cycloid spin structure, exhibits an antiferromagnetic core surrounded by a shell of uncompensated spins. Such magnetization-moment anticorrelation can be due to a surface to volume ratio effect.

Additionally, FIG. 5(e) shows magnetization hysteresis loops at 300 K and 2 K, on BFO NPs calcined at 600° C. Room temperature hysteresis loop exhibit superparamagnetic-like behavior with a very week ferromagnetic component (as stated before), with a 22 Oe coercive field. Regarding to low temperature hysteresis loop, coercive field increases to 340 Oe and NPs magnetism become predominantly ferromagnetic. Interestingly, a closer inspection of the magnetization, near zero field, shows a horizontal shift, see FIG. 5(f). Such a phenomenon is usually associated with an Exchange Bias (EB) effect, originated from the spin's interaction at the interface between ferromagnetic and antiferromagnetic layers. This effect is observed at low temperatures close 2 K. In our NPs, such effect could be associated with a core-shell structure of NPs with an antiferromagnetic core and a ferromagnetic shell. EB field has been calculated with the left (H_{C1}) and right (H_{C2}) coercive fields as H_{EB}=−(H_{c1}+H_{c2})/2. The hysteresis loop taken at 2 K has a H_{EB} of 56 Oe, while H_{EB} taken at room temperature is zero.

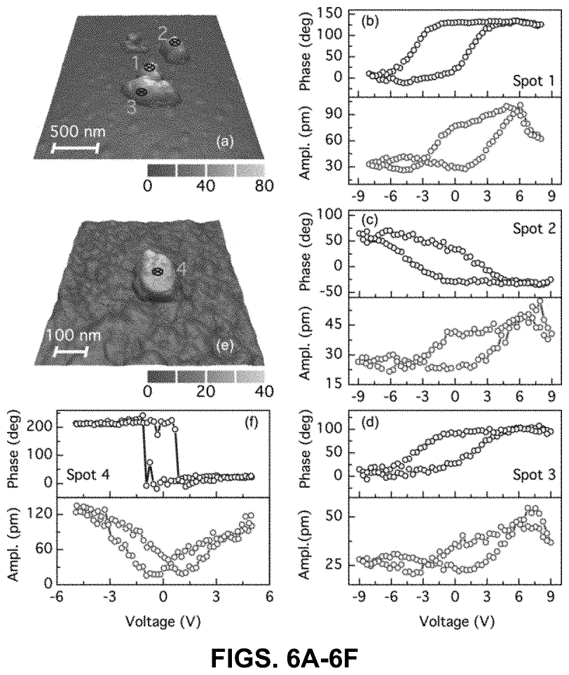

FIG. 6(a) shows AFM topography of dispersed BFO NPs calcined at 630° C. on an Au/Ti/SiO₂/Si substrate. Such NPs agglomerations have lateral sizes of several hundred nanometers, while thickness ranges from 45 nm to 70 nm, approximately. We have performed local measurements of amplitude and phase piezoelectric hysteresis curves, on marked spots inside the AFM picture employing the switching-spectroscopy PFM method (SS-PFM), results are shown in FIG. 6(b,d). Phase hysteresis loops correspond to ferroelectric behavior with coercive fields between 2.55 V and 2.65 V. The small difference in values of the coercive fields can relate to the NP size or to the direction polar vector for switching. Interestingly the polarization phase switching is near to 140° and approximately to 109° and 71° in FIG. 6(d,e), respectively. Such values are consistent with the values predicted by the switching phase mechanism expected for rhombohedral BFO⁷. We calculate the area of the phase-voltage hysteresis loops¹⁴, for spots 1 to 3 and obtained the respective values 764.8 a.u., 548.9 a.u., and 499.4 a.u. corresponding to NPs of 70 nm, 50 nm and 45 nm sizes. It can be noted that the area mostly decreases with the NP size. The corresponding piezoelectric amplitude hysteresis for each spot, taken simultaneously, show typical butterfly shape loops corroborating the ferroelectric properties of BFO NPs. From these we calculated the local longitudinal piezoelectric coefficient d₃₃ for spots 1, 2 and 3, the respective values are nearly to 7.74 μmV⁻¹, 2.48 μmV⁻¹ and 2.16 μmV⁻¹. Thus, d₃ coefficient mostly decrease with the NPs size similar to the switching area. The above results suggest that the ferroelectric switching can be tuned with the NP size. In addition, FIG. 6(e,f) shows the AFM topography and local PFM piezoelectric hysteresis loops of NPs calcined at 600° C. and dispersed on a Ag/Ti/SiO₂/Si substrate. Piezoelectric curves were taken on the spot 4 marked on the topography image of the NP with size close to 25 nm. Phase hysteresis loop have a coercive field close to 1.5 V and a phase switching near to 180° C. corresponding to a ferroelectric behavior. Regarding to the amplitude piezoelectric hysteresis loop, this local measurement exhibits a typical and well-shaped butterfly. Calculating the coefficient du we obtain a value near to 13.6 μmV⁻¹. This can be observed a change in the coercive fields as well as d₃ coefficient regarding to the calcined at 630° C. sample results. The probable cause of such behavior is the change of bottom electrode from Au to Ag, changing with this the depletion layer at the electrode-NP interface and thus the measured piezoelectric properties.

From the foregoing, it will be seen that aspects herein are well adapted to attain all the ends and objects hereinabove set forth together with other advantages which are obvious, and which are inherent to the structure.

It will be understood that certain features and subcombinations are of utility and may be employed without reference to other features and subcombinations. This is contemplated by and is within the scope of the claims.

Since many possible aspects may be made without departing from the scope thereof, it is to be understood that all matter herein set forth or shown in the accompanying drawings is to be interpreted as illustrative and not in a limiting sense.

Various modifications and variations can be made to the compounds, compositions and methods described herein. Other aspects of the compounds, compositions and methods described herein will be apparent from consideration of the specification and practice of the compounds, compositions and methods disclosed herein. It is intended that the specification and examples be considered as exemplary.

What is claimed:

1. A composite comprising a conductive framework and a plurality of nanoparticles comprising a multiferroic compound incorporated within the metal-organic framework.

2. The composite of claim 1, wherein the multiferroic compound comprises BiFeO₃ (BFO).

3. The composite of claim 2, wherein the multiferroic compound comprises BiFeO₃ nanoparticles calcined at temperature of from about 400° C. to about 650° C.

4. The composite of claim 2, wherein the multiferroic compound is produced by (a) admixing a Bi⁺³ compound with a Fe⁺³ compound in water to produce a first composition, (b) adding a glycol to the first composition to produce a second composition, and (c) heating the second composition at temperature of from about 400° C. to about 650° C. to produce the multiferroic compound.

5. The composite of claim 4, wherein the Bi⁺³ compound is BiX₃ and the Fe⁺³ compound is FeX₃, where X is a nitrate group or a halide.

6. The composite of claim 4, wherein the Bi⁺³ compound and the Fe⁺³ compound are in equimolar amounts.

7. The composite of claim 4, wherein the Bi⁺³ compound and the Fe⁺³ compound are admixed in water from about 20° C. to about 30° C.

8. The composite of claim 4, further comprising adding an organic acid to the first composition and heating the first composition at a temperature of from about 50° C. to about 100° C.

9. The composite of claim 4, wherein the glycol comprises ethylene glycol, propylene glycol, or a combination thereof.

10. The composite of claim 4, wherein step (b) is performed at a temperature of from about 80° C. to about 100° C.

11. The composite of claim 4, wherein BFO has a rhombohedral perovskite structure with an R3c space group symmetry.

12. The composite of claim 4, wherein the nanoparticles have a mean diameter of from 1 nm to 100 nm.

13. The composite of claim 1, wherein the nanoparticles are incorporated into the metallic organic framework chemical vapor deposition, solid grinding, liquid impregnation, and double solvent methods.

14. The composite of claim 1, wherein the conductive framework comprises a metal-organic framework.

15. A system comprising the composite of claim 1 for use in quantum information processing (QIP).

16. A sensor comprising the composite of claim 1.
